(19) United States
(12) Patent Application Publication
(10) Pub. No.: US 2021/0359121 A1
(43) Pub. Date: Nov. 18, 2021

(54) HIGH LINEARITY HEMT DEVICE AND PREPARATION METHOD THEREOF

(71) Applicant: Xidian University, Xi'an (CN)

(72) Inventors: Xuefeng Zheng, Xi'an (CN); Xiaohua Ma, Xi'an (CN); Zhenling Tang, Xi'an (CN); Peijun Ma, Xi'an (CN); Ming Du, Xi'an (CN); Minhan Mi, Xi'an (CN); Yunlong He, Xi'an (CN); Yang Lu, Xi'an (CN); Xiaohu Wang, Xi'an (CN); Chong Wang, Xi'an (CN); Yue Hao, Xi'an (CN)

(21) Appl. No.: 17/355,644

(22) Filed: Jun. 23, 2021

Related U.S. Application Data
(63) Continuation of application No. PCT/CN2021/082805, filed on Mar. 24, 2021.

(30) Foreign Application Priority Data
May 13, 2020 (CN) 202010402529.1
May 13, 2020 (CN) 202010402538.0
May 13, 2020 (CN) 202010403434.1

(51) Int. Cl. H01L 29/778; H01L 29/20

(52) U.S. Cl. CPC H01L 29/7786; H01L 29/2003

(57) ABSTRACT

A high electron mobility transistor (HEMT) device is provided. The HEMT device includes a substrate layer, a buffer layer, a barrier layer, and a metallic electrode layer sequentially arranged in that order from bottom to top. The metallic electrode layer includes a source electrode, a gate electrode and a drain electrode sequentially arranged in that order from left to right. The barrier layer may include m number of fluorine-doped regions arranged in sequence, where m is a positive integer and m≥2. The HEMT device can realize a relative stability of transconductance in a large range of a gate-source-bias through mutual compensation of transconductances in the fluorine-doped regions with different fluorine-ion concentrations of the barrier layer under the gate electrode, and the HEMT device has a good linearity without the need of excessive adjustments of material structure and device.

### FIELD OF THE DISCLOSURE

The disclosure relates to the field of semiconductor technologies, and more particularly to a high linearity high electron mobility transistor (HEMT) device and a preparation method thereof.

### BACKGROUND OF THE DISCLOSURE

With the popularization of 5G communication technology and the development of 6G communication technology, devices based on traditional first-generation semiconductor material represented by silicon (Si) or second-generation semiconductor material represented by gallium arsenide (GaAs) are gradually unable to meet the increasing frequency demands. Therefore, a third-generation semiconductor material represented by gallium nitride (GaN) has received widespread attentions. Compared with Si and GaAs, GaN has advantages of a wider band gap, higher critical field and higher electron velocity, etc., and therefore GaN can achieve faster operating speed, as well as enhanced reliability. Especially for high electron mobility transistors (HEMTs) based on AlGaN/GaN heterojunctions, benefiting from the high-density and high-mobility two-dimensional electron gas (2DEG) formed at the heterojunction interface, extremely high operating speed can be achieved in these devices. As a result, GaN HEMTs show broad application prospects in communications and other fields.

In the field of communication, the linearity of semiconductor devices is an important parameter. However, for a conventional HEMT device, due to factors such as decrease in electron saturation speed and increase in series resistance, the transconductance of GaN HEMTs will fall off soon after reaching its peak value as gate bias increases. This decrease in transconductance will affect the linearity of the device and thus limit the linearity operating range of the device. Therefore, in order to improve device linearity, several approaches have been proposed, including a gradient barrier layer, nanowire channels, etc. In addition, another technique named transconductance compensation has also been reported to enhance device linearity. The main idea of this transconductance compensation method is to integrate devices with different transconductance peaks in one device, hence the decrease in transconductance of one part of the device can get compensated by that of other parts, resulting in a much flatter transconductance curve. Up to now, two examples of transconductance compensation method have been reported, one is the graded channel width in aforementioned nanowire channel devices, while another approach is a transitional-recessed-gate technology which can form a barrier layer with graded thickness.

However, the use of the gradient component barrier structure requires a barrier layer with a high aluminum (Al) composition, which would lead to the deterioration of surface quality of the device. Besides, the uses of the nanowire channels would involve an etching process in the preparation processes, which would cause excessive etching damage, and remaining channel sidewalls would also produce excessive parasitic capacitances, so that the performance of device may get degraded. In addition, the transitional-recessed-gate technology requires a precise etching depth control to the barrier layer, and thus the process is too complex.

### SUMMARY OF THE DISCLOSURE

In order to solve the above problems in the related arts, the disclosure provides a HEMT device and a preparation method thereof. The technical problems to be solved by the disclosure can be realized by following technical solutions.

In particular, a HEMT device exemplarily includes a substrate layer, a buffer layer, a barrier layer, and a metallic electrode layer sequentially arranged in that order along a first direction e.g., a direction from bottom to top. The metallic electrode layer includes a source electrode, a gate electrode and a drain electrode sequentially arranged in that order along a second direction intersecting with the first direction, e.g., a direction from left to right. The barrier layer includes m number of fluorine-doped regions F1˜Fm arranged in sequence, and the m number of fluorine-doped regions F1˜Fm include at least two different fluorine-ion concentrations. Herein, each of the m number of fluorine-doped regions F1˜Fm is with one of the at least two different fluorine-ion concentrations.

In one embodiment of the disclosure, the HEMT device further includes a dielectric layer, and the dielectric layer is disposed between the source electrode and the drain electrode. The gate electrode is disposed above the dielectric layer.

Another embodiment of the disclosure provides a HEMT device. The HEMT device includes a substrate layer, a buffer layer, a barrier layer, and a metallic electrode layer sequentially arranged in that order along a first direction e.g., a direction from bottom to top. The metallic electrode layer includes a source electrode and a drain electrode respectively located at two ends of itself. A dielectric layer is disposed between the source electrode and the drain electrode, and a gate electrode of the metallic electrode layer is disposed on the dielectric layer. The dielectric layer includes m number of fluorine-doped regions F1˜Fm arranged in sequence, where m is a positive integer and m≥2, and fluorine-ion concentrations of the m number of fluorine-doped regions F1˜Fm include at least two different fluorine-ion concentrations.

In one embodiment of the disclosure, the m number of fluorine-doped regions F1˜Fm are located below the gate electrode and arranged in sequence along a widthwise direction of the gate electrode.

In one embodiment of the disclosure, the fluorine-ion concentrations of the m number of fluorine-doped regions F1˜Fm are progressively increased or decreased along a direction from the fluorine-doped region F1 to the fluorine-doped region Fm.

In one embodiment of the disclosure, the fluorine-ion concentrations of the m number of fluorine-doped regions F1˜Fm are progressively increased or decreased along a direction from each of the fluorine-doped region F1 and the fluorine-doped region Fm to a middle fluorine-doped region of the m number of fluorine-doped regions F1˜Fm.

In one embodiment of the disclosure, the fluorine-ion concentrations of the m number of fluorine-doped regions include two different fluorine-ion concentrations. The fluorine-doped regions of the m number of fluorine-doped regions F1˜Fm having one of the two different fluorine-ion concentrations and the fluorine-doped regions of the m number of fluorine-doped regions F1˜Fm having the other one of the two different fluorine-ion concentrations are alternately arranged.

In one embodiment of the disclosure, the HEMT device further includes at least one selected from a group consisting of a nucleation layer, an interlayer, a cap layer, and a passivation layer. The nucleation layer is arranged between the substrate layer and the buffer layer. The interlayer is arranged between the buffer layer and the barrier layer. The cap layer is arranged between the barrier layer and the metallic electrode layer. The passivation layer is arranged above the barrier layer and located among the source electrode, the gate electrode, and the drain electrode.

Still another embodiment of the disclosure provides a HEMT device. The HEMT device includes a substrate layer, a buffer layer, a barrier layer, and a metallic electrode layer sequentially arranged in that order along a first direction, e.g., a direction from bottom to top. The metallic electrode layer includes a source electrode, a gate electrode and a drain electrode sequentially arranged in that order along a second direction intersecting with the first direction, e.g., a direction from left to right. The barrier layer includes m number of negatively-charged-ion doped regions F1˜Fm arranged in sequence, where m is a positive integer and m≥2. The negatively-charged-ion concentrations of the m number of negatively-charged-ion doped regions include at least two different negatively-charged-ion concentrations. Herein, each of the m number of negatively-charged-ion doped regions is with one of the at least two different negatively-charged-ion concentrations.

Even still another embodiment of the disclosure provides a HEMT device. The HEMT device includes a substrate layer, a buffer layer, a barrier layer, and a metallic electrode layer sequentially arranged in that order along a first direction, e.g., a direction from bottom to top. The metallic electrode layer includes a source electrode and a drain electrode respectively located at two ends of itself. A dielectric layer is disposed between the source electrode and the drain electrode, and a gate electrode of the metallic electrode layer is disposed on the dielectric layer. The dielectric layer includes m number of negatively-charged-ion doped regions F1˜Fm arranged in sequence, where m is a positive integer and m≥2, and negatively-charged-ion concentrations of the m number of negatively-charged-ion doped regions include at least two different negatively-charged-ion concentrations.

Further another embodiment of the disclosure provides a preparation method of a HEMT device, including:
step 1: obtaining an epitaxial substrate and cleaning the epitaxial substrate, and the epitaxial substrate including a barrier layer;
step 2: forming a source electrode and a drain electrode on the barrier layer;
step 3: performing a mesa etching onto the epitaxial substrate to form an isolation mesa on the barrier layer;
step 4: performing fluorine-ion injections into the barrier layer to form multiple (i.e., more than one) fluorine-doped regions, the multiple fluorine-doped regions being located between the source electrode and the drain electrode; and
step 5: forming a gate electrode on the multiple fluorine-doped regions to complete the preparation of HEMT device.

In one embodiment of the disclosure, the preparation method further includes: after the step 4, depositing a dielectric layer on the barrier layer, and the dielectric layer being arranged between the source electrode and the drain electrode.

In one embodiment of the disclosure, the step 4 includes:
(4a) forming a first fluorine-injection region on the barrier layer by photolithographing;
(4b) performing a fluorine-ion injection into the first fluorine-injection region to form a first fluorine-doped region of the multiple fluorine-doped regions, a fluorine-ion concentration of the first fluorine-doped region being n₁; and
(4c) forming an i-th fluorine-injection region on the barrier layer by photolithographing, and performing a fluorine-ion injection into the i-th fluorine-injection region to form an i-th fluorine-doped region of the multiple fluorine-doped regions, a fluorine-ion concentration of the i-th fluorine-doped region being nᵢ, and nᵢ₋₁<nᵢ or nᵢ₋₁>nᵢ, and 2≤i≤m, and i and m being positive integers respectively, and m being the number of the multiple fluorine-doped regions. Herein, nᵢ₋₁ is a fluorine-ion concentration of the (i−1)-th fluorine-doped region of the multiple fluorine-doped regions.

In another embodiment of the disclosure, the step 4 includes:
(41) forming a first fluorine-injection region and an m-th fluorine-injection region on the barrier layer by photolithographing, m being the number of the plurality of fluorine-doped regions;
(42) performing a fluorine-ion injection into the first fluorine-injection region and the m-th fluorine-injection region to respectively form a first fluorine-doped region and an m-th fluorine-doped region of the multiple fluorine-doped regions, a fluorine-ion concentration of the first fluorine-doped region being n₁, a fluorine-ion concentration of the m-th fluorine-doped region being nₘ, and n₁₌nₘ; and
(43) forming a (1+j)-th fluorine-injection region and a (m−j)-th fluorine-injection region on the barrier layer by photolithographing, and performing the fluorine-ion injection into the (1+j)-th fluorine-injection region and the (m−j)-th fluorine-injection region to respectively form a (1+j)-th fluorine-doped region and a (m−j)-th fluorine-doped region, a fluorine-ion concentration of the (1+j)-th fluorine-doped region being n₁₊ⱼ, a fluorine-ion concentration of the (m−j)-th fluorine-doped region being nₘ₋ⱼ, and nᵢ₊ⱼ₌nₘ₋ⱼ, and nⱼ<n₁₊ⱼ or nⱼ>n₁₊ⱼ, and,

$$1 \leq j \leq \frac{m - 1}{2} ,$$

when m is an odd number;

$$1 \leq j \leq \frac{m}{2} - 1 ,$$

when m is an even number.
Herein, nⱼ is a fluorine-ion concentration of the j-th fluorine-doped region of the multiple fluorine-doped regions.

In still another embodiment of the disclosure, the step 4 includes: forming k-th fluorine-injection regions on the barrier layer by photolithographing, and performing a fluorine-ion injection into the k-th fluorine-injection regions to form multiple fluorine-doped regions with a same fluorine-ion concentration, where k is odd numbers greater than 1, or k is even numbers greater than 1, and k≤m.

In even still another embodiment of the disclosure, the step 4 further includes: forming l-th fluorine-injection regions on the barrier layer by photolithographing, and performing a fluorine-ion injection into the l-th fluorine-injection regions to form another multiple fluorine-doped regions with a same fluorine-ion concentration, where l is even numbers greater than 1 when k is odd numbers greater than 1, or l is odd numbers greater than 1 when k is even numbers greater than 1, and l≤m.

Further still another embodiment of the disclosure provides a preparation method of a HEMT device, including:
step A: obtaining an epitaxial substrate and cleaning the epitaxial substrate, and the epitaxial substrate including a barrier layer;
step B: forming a source electrode and a drain electrode on the barrier layer;
step C: performing a mesa etching on the epitaxial substrate to form an isolation mesa on the barrier layer;
step D: depositing a dielectric layer on the barrier layer between the source electrode and the drain electrode;
step E: injecting fluorine ions into the dielectric layer to form multiple fluorine-doped regions, the multiple fluorine-doped regions being located between the source electrode and the drain electrode; and
step F: forming a gate electrode overlying a region of the dielectric layer formed with the multiple fluorine-doped regions, to complete the preparation of the HEMT device.

Embodiments of the disclosure mainly can achieve beneficial effects as follows.

1. the HEMT device as provided by the disclosure can realize a relative stability of transconductance in a large range of gate-source-bias (bias voltage between the gate electrode and the source electrode) through mutual compensation of transconductances in fluorine-doped regions with different fluorine-ion concentrations of the barrier layer or the dielectric layer under/below the gate electrode, and the HEMT device can have a good linearity without the need of excessive adjustments of structures of device and materials.

2. the HEMT device provided by the disclosure as a MIS-HEMT device (Metal-Insulator-Semiconductor High Electron Mobility Transistor), by the application/use of the dielectric-gate structure, can reduce a gate leakage current, increase a withstand voltage of the device, and widen a gate-voltage swing of the device in a normal operation, and thereby further improve the linearity of device while improving characteristics of the device such as a gain and a power-added efficiency.

3. the HEMT device as provided by the disclosure has a simple manufacturing process and a good compatibility, which is convenient to device preparation and process adjustment, and moreover an additional effect as introduced is small and thus can achieve higher feasibility and repeatability.

4. the structure of the HEMT device as provided by the disclosure is similar to that of the conventional HEMT devices and thus can be compatible with other relevant optimization solutions such as a field-plate (FP) structure, and therefore can realize characteristics such as high breakdown voltage and high output current while maintaining a high linearity.

The disclosure will be further described in detail below in conjunction with accompanying drawings and embodiments.

### BRIEF DESCRIPTION OF THE DRAWINGS

FIG. 1 is a schematic structural view of a high linearity HEMT device according to an embodiment of the disclosure.

FIG. 2 is a schematic cross-sectional view at a gate electrode of the high linearity HEMT device shown in FIG. 1.

FIG. 3 is a schematic top view of an arrangement of m number of fluorine-doped regions F1˜Fm of the high linearity HEMT device shown in FIG. 1.

FIG. 4 is a schematic structural view of another high linearity HEMT device according to an embodiment of the disclosure.

FIG. 5 is a schematic structural view of still another high linearity HEMT device according to an embodiment of the disclosure.

FIG. 6 is a flowchart of a preparation method of the high linearity HEMT device shown in FIG. 1.

FIG. 7 is a flowchart of another preparation method of the high linearity HEMT device shown in FIG. 1.

FIGS. 8a-8f are schematic views of a preparation process of the high linearity HEMT device shown in FIG. 1.

FIGS. 9a-9b are schematic views of a fluorine-ion injection process according to an embodiment of the disclosure.

FIGS. 10a-10b are schematic views of another fluorine-ion injection process according to an embodiment of the disclosure.

FIG. 11 is a flowchart of a preparation method of the high linearity HEMT device shown in FIG. 4.

FIG. 12 is a flowchart of a preparation method of the high linearity HEMT device shown in FIG. 5.

### DETAILED DESCRIPTION OF EMBODIMENTS

The disclosure will be further described in detail in combination with specific embodiments, but embodiments of the disclosure are not limited to these.

### First Embodiment

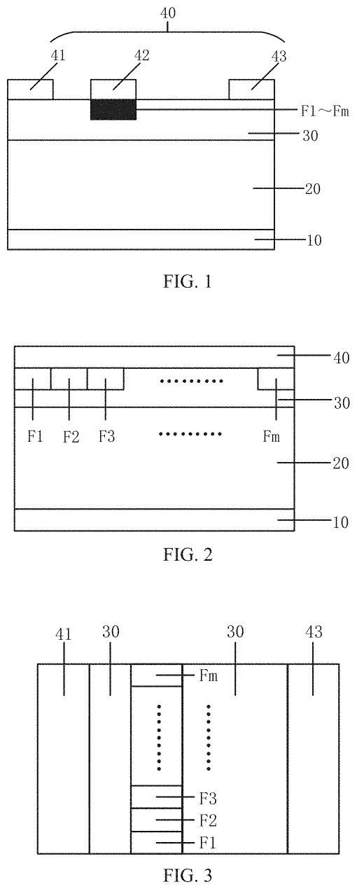

Referring to FIG. 1, FIG. 1 is a schematic structural view of a high linearity HEMT device provided by this embodiment of the disclosure. The HEMT device includes: a substrate layer 10, a buffer layer 20, a barrier layer 30, and a metallic electrode layer 40 sequentially arranged in that order from bottom to top (e.g., along a vertical direction in FIG. 1). The metallic electrode layer 40 includes a source electrode 41, a gate electrode 42, and a drain electrode 43 sequentially arranged in that order from left to right (e.g., along a horizontal direction in FIG. 1). The barrier layer 30 includes m number of negatively-charged-ion doped regions e.g., fluorine-doped regions F1˜Fm arranged in sequence, where m is a positive integer and m≥2. Fluorine-ion concentrations of the m number of fluorine-doped regions F1˜Fm include at least two different fluorine-ion concentrations. In other words, each of the m number of fluorine-doped regions F1˜Fm is with one of the at least two different fluorine-ion concentrations.

Further, the fluorine-doped regions F1˜Fm exemplarily are located below the gate electrode 42 and arranged in sequence along a widthwise direction of the gate electrode 42 (e.g., a horizontal direction in FIG. 2).

Referring to FIG. 2 and FIG. 3, FIG. 2 is a schematic cross-sectional view at the gate electrode of the HEMT device shown in FIG. 1, and FIG. 3 is a schematic top view of an arrangement of m number of fluorine-doped regions F1˜Fm of the HEMT device shown in FIG. 1.

Specifically, the barrier layer 30 located below the gate electrode 42 is divided into the fluorine-doped regions F1˜Fm arranged in sequence along the widthwise direction of the gate electrode 42, and different fluorine-doped regions are doped with different fluorine-ion concentrations. A doping of fluorine ions can change a concentration of 2DEG (two-dimensional electron gas) of a corresponding region under the gate electrode 42, and thus a threshold voltage of the corresponding region is adjusted. Further, an adjustment effect of the doping of fluorine ions applied to the threshold voltage of the corresponding region is affected by the doped fluoride-ion concentration. Therefore, the HEMT device can be regarded as a parallel-connection structure of several HEMT devices with different transconductances. Owing to the parallel-connection structure, the transconductances of the respective discrete HEMT devices are mutually compensated, so that a transconductance value can be relatively stable in a large range of gate-source-bias (i.e., a bias voltage between the gate electrode and the source electrode).

Further, the fluorine-ion concentrations of the fluorine-doped regions F1˜Fm may be progressively increased or decreased along a direction from the fluorine-doped region F1 to the fluorine-doped region Fm.

Specifically, the fluorine-ion concentrations of the fluorine-doped regions F1˜Fm can be expressed as n₁, n₂, n₃, . . . , nₘ respectively, and n₁<n₂< . . . <nₘ₋₁<nₘ, or n₁>n₂> . . . >nₘ₋₁>nₘ. As a result, the fluorine-doped regions as a whole having a progressively increased or decreased fluorine-ion concentration from one end to the other end can be realized.

In another embodiment of the disclosure, the fluorine-ion concentrations of the fluorine-doped regions F1˜Fm may be progressively increased or decreased along a direction from each of the fluorine-doped region F1 and the fluorine-doped region Fm to a middle fluorine-doped region of the fluorine-doped regions F1˜Fm.

Specifically, the fluorine-ion concentrations of the fluorine-doped regions F1˜Fm are progressively increased along the direction from each of the fluorine-doped region F1 and the fluorine-doped region Fm to the middle fluorine-doped region of the fluorine-doped regions F1˜Fm. The fluorine-ion concentrations of the fluorine-doped region F1 and the fluorine-doped region Fm both can be expressed as n₁, and the fluorine-ion concentrations of the fluorine-doped region F2 and the fluorine-doped region Fm−1 both can be expressed as n₂, and so on, n₁<n₂< . . . .

Or, the fluorine-ion concentrations of the fluorine-doped regions F1˜Fm may be progressively decreased along the direction from each of the fluorine-doped region F1 and the fluorine-doped region Fm to the middle fluorine-doped region of the fluorine-doped regions F1˜Fm, and meet the requirement of n₁>n₂> . . . .

In still another embodiment of the disclosure, the fluorine-ion concentrations of the fluorine-doped regions F1˜Fm can include two different fluorine-ion concentrations. The fluorine-doped regions of the fluorine-doped regions F1˜Fm having one of the two different fluorine-ion concentrations and the fluorine-doped regions of the fluorine-doped regions F1˜Fm having the other one of the two different fluorine-ion concentrations are alternately arranged. For example, it can be that the fluorine-ion concentrations of odd numbered fluorine-doped regions such as the fluorine-doped region F1, the fluorine-doped region F3 and so on are the same, and the fluorine-ion concentrations of even numbered fluorine-doped regions such as the fluorine-doped region F2, the fluorine-doped region F4 and so on are the same. Alternatively, it can be that the odd numbered fluorine-doped regions are doped with fluorine ions, while the even numbered fluorine-doped regions are not doped with fluorine ions; or, the even numbered fluorine-doped regions are doped with fluorine ions, while the odd numbered fluorine-doped regions are not doped with fluorine ions.

The above only exemplarily lists several fluorine-ion concentrations distribution manners of the fluorine-doped regions F1˜Fm, and in actual applications the fluorine-ion concentrations are not specifically limited, as long as that the fluorine-doped regions F1˜Fm include at least two different fluorine-ion concentrations.

In the illustrated embodiment, the substrate layer 10 can be a substrate of silicon, sapphire, silicon carbide, or any combination thereof. A material of the buffer layer 20 can be GaN or the like. A material of the barrier layer 30 can be AlGaN, InAlN, or the like.

Further, the device in the illustrated embodiment may further include at least one selected from a group consisting of a nucleation layer, an interlayer, a cap layer, and a passivation layer. The nucleation layer is arranged between the substrate layer 10 and the buffer layer 20. The interlayer is arranged between the buffer layer 20 and the barrier layer 30. The cap layer is arranged between the barrier layer 30 and the metallic electrode layer 40. The passivation layer is arranged above the barrier layer 30 and located among the source electrode 41, the gate electrode 42 and the drain electrode 43.

In a practical application, in order to obtain a high-quality epitaxial structure, the nucleation layer can be added between the substrate 10 and the buffer layer 20, and a material of the nucleation layer can be aluminum nitride (AlN). Further, in order to obtain a high concentration of 2DEG, the interlayer can be added between the buffer layer 20 and the barrier layer 30, and a material of the interlayer can be AlN. In a case, in order to obtain high-quality ohmic contact and Schottky contact, and improve a carrier mobility, the cap layer can be added between the barrier layer 30 and the metallic electrode layer 40, and a material of the cap layer can be gallium nitride (GaN), etc. In addition, in order to optimize electrical characteristics of the HEMT device, the passivation layer can be prepared in regions among the electrodes above the barrier layer 30, and a material of the passivation layer can be silicon nitride (SiN), etc.

In summary, the high linearity HEMT device as provided in the illustrated embodiment, in the widthwise direction of the gate electrode 42, by mutual transconductance compensations and interactions among a series of devices with transconductance peaks similar to but shifted from one another, can realize the stability of transconductance in a large range of gate-source-bias and thereby improve the linearity of device. Compared with the related arts, the illustrated embodiment does not need to redesign from a physical mechanism of transconductance characteristic of the HEMT device itself, and can directly use a mutual compensation of devices with different transconductance characteristics. As a result, it can avoid excessive adjustments of structures of device and materials and reduce the design difficulty, while the linearization effect is not weakened.

In addition, the structure of the high linearity HEMT device provided by the illustrated embodiment is similar to that of the conventional HEMT devices and thus can be compatible with other relevant optimization solutions such as a field-plate (FP) structure, and therefore can achieve characteristics such as high breakdown voltage and high output current while maintaining a high linearity.

### Second Embodiment

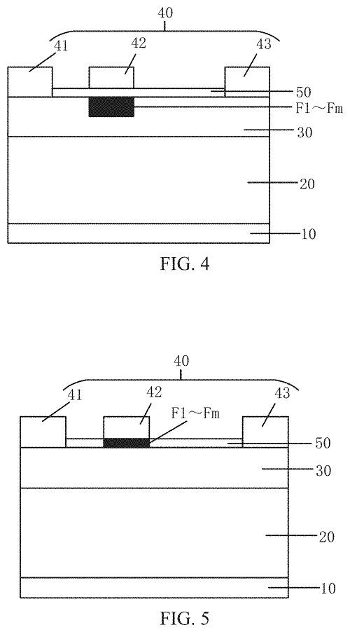

Referring to FIG. 4, FIG. 4 is a schematic structural view of another high linearity HEMT device provided by this embodiment of the disclosure. On the basis of the structure of the high linearity HEMT device as provided by the first embodiment, the HEMT device in the second embodiment may further include a dielectric layer 50. The dielectric layer 50 is disposed between the source electrode 41 and the drain electrode 43, and the gate electrode 42 is disposed above the dielectric layer 50.

Further, the illustrated embodiment realizes a MIS-HEMT device (Metal-Insulator-Semiconductor High Electron Mobility Transistor) with high-linearity by the application/use of a dielectric material (e.g., the dielectric layer 50) with a high dielectric constant, and thus can maintain high gate control capability and device transconductance while suppressing a leakage current. In addition, the high linearity HEMT device as provided by the illustrated embodiment, by way of the application/use of a dielectric-gate structure, can reduce a gate leakage current, increase a withstand voltage of the device and widen a gate voltage swing of the device in a normal operation, and thereby further improve the linearity of the device while improving characteristics of the device such as a gain and a power additional efficiency.

It should be noted that the other structures of the HEMT device provided in the illustrated embodiment, such as the fluorine-doped regions, the nucleation layer, the interlayer, the cap layer, are same as those of the high linearity HEMT device provided in the first embodiment, and thus will not be repeated herein.

### Third Embodiment

Referring to FIG. 5, FIG. 5 is a schematic structural view of another high linearity HEMT device as provided by this embodiment of the disclosure. The HEMT device includes a substrate layer 10, a buffer layer 20, a barrier layer 30, and a metallic electrode layer 40 sequentially arranged in that order from bottom to top. The metallic electrode layer 40 includes a source electrode 41 and a drain electrode 43 respectively located at two ends of itself. A dielectric layer 50 is disposed between the source electrode 41 and the drain electrode 43, and a gate electrode 42 is disposed on the dielectric layer 50. The dielectric layer 50 includes m number of negatively-charged-ion doped regions e.g., fluorine-doped regions F1˜Fm arranged in sequence, where m is a positive integer and m≥2. Fluorine-ion concentrations of the fluorine-doped regions F1˜Fm include at least two different fluorine-ion concentrations.

The HEMT device as provided by the illustrated embodiment, by the application/use of a dielectric-gate structure, can reduce a gate leakage current, increase a withstand voltage of the device and widen a gate-voltage swing of the device in a normal operation, and thereby further improve the linearity of device while improving characteristics of the device such as a gain and a power-added efficiency. In addition, the illustrated embodiment defines the fluorine-doped regions in the dielectric layer 50 under the gate electrode 42, fluorine ions in such structure are far away from a conductive channel and are not easy to enter into the channel, so that the influence of fluorine ions applied onto a channel electron mobility can be avoided and the influence of fluorine-ion injection applied onto a transport characteristic of the device can be reduced.

It should be noted that the other structures of the high linearity HEMT device as provided in this embodiment such as the fluorine-doped regions, the nucleation layer, the interlayer, the cap layer, are same as those of the high linearity HEMT device as provided in the first embodiment, and thus will not be repeated herein.

### Fourth Embodiment

This embodiment provides a high linearity HEMT device. The HEMT device exemplarily includes a substrate layer 10, a buffer layer 20, a barrier layer 30, and a metallic electrode layer 40 sequentially arranged in that order from bottom to top. The metallic electrode layer 40 includes a source electrode 41, a gate electrode 42, and a drain electrode 43 sequentially arranged in that order from left to right. The barrier layer 30 includes m number of negatively-charged-ion doped regions F1˜Fm arranged in sequence, where m is a positive integer and m≥2. Negatively-charged-ion concentrations of the m number of negatively-charged-ion doped regions F1˜Fm include at least two different negatively-charged-ion concentrations. In other words, each of the m number of negatively-charged-ion doped regions F1˜Fm is with one of the at least two different negatively-charged-ion concentrations.

The high linearity HEMT device as provided in the illustrated embodiment basically has the same structure as the device provided in the above first embodiment, and a difference only is that the negatively-charged-ion doped regions F1˜Fm can be injected/doped with fluorine ions, or doped with other types of negatively-charged-ions instead of the fluorine ions. The other types of negatively-charged-ions may be oxygen ions, nitrogen ions or chlorine ions, to modulate transconductances of regions under the gate electrode 42 and thereby achieve a high-linearity.

### Fifth Embodiment

This embodiment provides a high linearity HEMT device. The HEMT device exemplarily includes a substrate layer 10, a buffer layer 20, a barrier layer 30, and a metallic electrode layer 40 sequentially arranged in that order from bottom to top. The metallic electrode layer 40 includes a source electrode 41 and a drain electrode 43 respectively located at two ends of itself. A dielectric layer 50 is disposed between the source electrode 41 and the drain electrode 43, and a gate electrode 42 is disposed on the dielectric layer 50. The dielectric layer 50 includes m number of negatively-charged-ion doped regions F1˜Fm arranged in sequence, where m is a positive integer and m≥2. Negatively-charged-ion concentrations of the m number of negatively-charged-ion doped regions F1˜Fm include at least two different negatively-charged-ion concentrations. In other words, each of the m number of negatively-charged-ion doped regions F1˜Fm is with one of the at least two different negatively-charged-ion concentrations.

The high linearity HEMT device as provided in the illustrated embodiment basically has the same structure as the device provided in the third embodiment, and a difference only is that the negatively-charged-ion doped regions F1˜Fm can be injected/doped with fluorine ions, or doped with other types of negatively-charged-ion instead of the fluorine ions. The other types of negatively-charged-ion may be oxygen ions, nitrogen ions or chlorine ions, to modulate transconductances of regions under the gate electrode 42 and thereby achieve a high-linearity.

### Sixth Embodiment

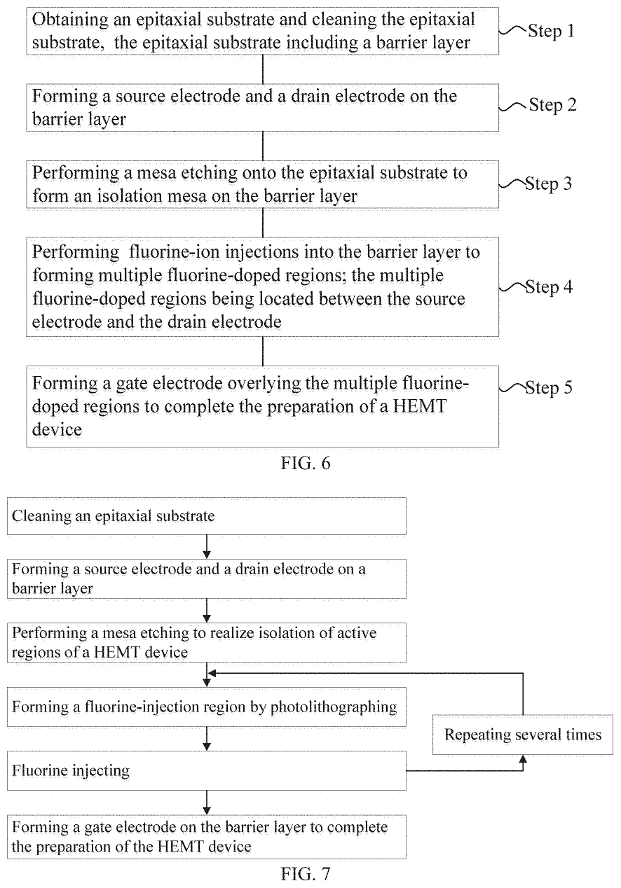

This embodiment provides a preparation method of a high linearity HEMT device, used to prepare the HEMT device as provided by the first embodiment. Referring to FIG. 6, FIG. 6 is a flowchart of a preparation method of the HEMT device shown in FIG. 1. The preparation method specifically includes the following step 1 through step 5.

Step 1: obtaining an epitaxial substrate and cleaning the epitaxial substrate, the epitaxial substrate including a barrier layer.

Specifically, the epitaxial substrate can include a sapphire substrate, a GaN buffer layer, and an aluminum gallium nitride (AlGaN) barrier layer sequentially arranged in that order from bottom to top.

In the illustrated embodiment, the obtained epitaxial substrate can further include a nucleation layer and an interlayer. The nucleation layer is located between the sapphire substrate and the GaN buffer layer, and the interlayer is located between the GaN buffer layer and the AlGaN barrier layer.

Step 2: forming a source electrode and a drain electrode on the barrier layer. More specifically, the step 2 may include the following sub-steps (2a)-(2d).

(2a) coating a photoresist glue on a surface of the epitaxial substrate and spinning the coated photoresist glue, to obtain a photoresist mask.

(2b) drying the epitaxial substrate, and forming a first mask layer by photolithography and development techniques.

(2c) evaporating a first metallic layer on a surface of the first mask layer to obtain source and drain metals.

(2d) removing the first mask layer and the first metal layer by a lift-off process and performing a rapid annealing, to form the source electrode and the drain electrode on the barrier layer.

In the illustrated embodiment, the first mask layer is with a mask pattern of source and drain regions, and the first metallic layer is a source-drain metallic layer.

Step 3: performing a mesa etching onto the epitaxial substrate to form an isolation mesa on the barrier layer. In particular, the step 3 may be a result of following sub-steps (3a)-(3c).

(3a) coating a photoresist glue on a surface of the structure obtained after the step 2 (hereinafter also referred to as a sample) and spinning the coated photoresist glue, to obtain a photoresist mask.

(3b) drying the sample and forming a mask pattern of the isolation mesa by lithography and development.

(3c) etching the sample formed with the mask pattern to form the isolation mesa on the barrier layer.

Step 4: performing fluorine-ion injections into the barrier layer to form multiple fluorine-doped regions. Herein the multiple fluorine-doped regions are located between the source electrode and the drain electrode.

Referring to FIG. 7, FIG. 7 is a flowchart of another preparation method of the high linearity HEMT device shown in FIG. 1. In an embodiment of the disclosure, the step 4 may include the following sub-steps (4a)-(4c).

(4a) forming/defining a first fluorine-injection region on the barrier layer by photolithographing.

(4b) performing a fluorine-ion injection into the first fluorine-injection region to form a first fluorine-doped region of the multiple fluorine-doped regions. A fluorine-ion concentration of the first fluorine-doped region is n₁.

(4c) forming/defining an i-th fluorine-injection region on the barrier layer by photolithographing and performing another fluorine-ion injection to the i-th fluorine-injection region to form an i-th fluorine-doped region of the multiple fluorine-doped regions. A fluorine-ion concentration of the i-th fluorine-doped region is nᵢ, and nᵢ₋₁<nᵢ or nᵢ₋₁>nᵢ, where 2≤i≤m, and i and m are positive integers respectively, and m is the number of the multiple fluorine-doped regions. Herein it is noted that, nᵢ₋₁ represents a fluorine-ion concentration of the (i−1)-th fluorine-doped region of the multiple fluorine-doped region.

Specifically, in the illustrated embodiment, the fluorine-ion injections are exemplarily carried out by a fluorine based reactive plasma etching process. A reaction gas is a CF₄ plasma, a power is 60-200 W, and an etching time is 50-300 seconds. The higher the power and the longer the injection time, the higher the injection concentrations are.

In the illustrated embodiment, since the fluorine-ion concentrations of the m number of fluorine-doped regions are progressively increased or decreased along a direction from one end to the other end, e.g., from the first fluorine-ion doped F1 to the m-th fluorine-doped region Fm, and thus in a specific preparation process, the fluorine-injection region is formed first and the fluorine-ion injection then is performed, and so on, until a series of m number of fluorine-doped regions with the fluorine-ion concentrations progressively increased from one end to the other end are obtained.

In another embodiment of the disclosure, the step 4 may include the following sub-steps (41)-(44) instead.

(41) forming a first fluorine-injection region and an m-th fluorine-injection region on the barrier layer by photolithographing.

(42) performing a fluorine-ion injection into the first fluorine-injection region and the m-th fluorine-injection region, to form a first fluorine-doped region and an m-th fluorine-doped region of the multiple fluorine-doped regions. A fluorine-ion concentration of the first fluorine-doped region is n₁, a fluorine-ion concentration of the mth fluorine-doped region is nₘ, and n₁₌nₘ;

(43) forming a (1+j)-th fluorine-injection region and a (m−j)-th fluorine-injection region on the barrier layer by photolithographing, and performing another fluorine-ion injection into the (1+j)-th fluorine-injection region and the (m−j)-th fluorine-injection region to respectively form a (1+j)-th fluorine-doped region and a (m−j)-th fluorine-doped region. A fluorine-ion concentration of the (1+j)-th fluorine-doped region is n₁₊ⱼ, a fluorine-ion concentration of the (m−j)-th fluorine-doped region is nₘ₋ⱼ, and n₁₊ⱼ₌nₘ₋ⱼ, where nⱼ<n₁₊ⱼ or nⱼ>n₁₊ⱼ. Herein, it is noted that nⱼ represents a fluorine-ion concentration of a j-th fluorine-doped region of the m number of fluorine-doped regions F1˜Fm. Moreover,

$$1 \leq j \leq \frac{m - 1}{2} ,$$

when m is an odd number;

$$1 \leq j \leq \frac{m}{2} - 1 ,$$

when m is an even number.

In the illustrated embodiment, because the fluorine-ion concentrations of the m number of fluorine-doped regions F1˜Fm are progressively increased or decreased along a direction from each of two opposite ends to a middle, e.g., from each of the fluorine-doped region F1 and the fluorine-doped region Fm to a middle fluorine-doped region of the m number of fluorine-doped regions F1˜Fm, two fluorine-injection regions (as a group of fluorine-injection regions) which would be injected with a same fluorine-ion concentration can be formed simultaneously and then are performed with the fluorine-ion injection, and subsequently a next group of fluorine-doped regions with another same concentration can be prepared, and so on, until a series of m number of fluorine-doped regions whose fluorine-ion concentrations are progressively increased or decreased along a direction from each of the two opposite ends to the middle are formed.

In still another embodiment of the disclosure, the step 4 may include: forming kth fluorine-injection regions on the barrier layer by photolithographing, and performing a fluorine-ion injection into the k-th fluorine-injection regions to form multiple fluorine-doped regions with a same fluorine-ion concentration, where k is odd numbers greater than 1, or k is even numbers greater than 1, and k≤m.

In other words, by performing the fluorine-ion injection into the fluorine-injection regions spaced from one another, fluorine-ion doped regions with a certain concentration of fluorine ion and the rest regions with zero concentration can be formed and alternately arranged.

In addition, after the above step, it may further include: forming l-th fluorine-injection regions on the barrier layer by photolithographing, and performing another fluorine-ion injection into the l-th fluorine-injection regions to form multiple fluorine-doped regions with another same fluorine-ion concentration, where l is even numbers greater than 1 when k is odd numbers greater than 1, or l is odd numbers greater than 1 when k is even numbers greater than 1, and l≤m.

As a result, by performing two times of fluorine-ion injections into the alternately arranged fluorine-injection regions, alternately arranged fluorine-ion doped regions with two different fluorine-ion concentrations are formed consequently.

Further, in order to activate the injected/doped fluorine ions, a post annealing process can be carried out immediately after the fluorine-ion injections in the step 4. An annealing temperature is above 340° C., and an annealing time is more than 10 minutes. In the preparation process provided by the disclosure, the annealing is carried out after the gate electrode is made/formed, or is carried out after the fluorine-ion injections instead in an actual application.

Step 5: forming a gate electrode on the multiple fluorine-doped regions to complete the preparation of the high linearity HEMT device. The step 5 actually may be a result of the following sub-steps (5a)-(5d).

(5a) coating a photoresist glue on a surface of the structure/sample obtained after the step 4 and spinning the coated photoresist glue, to obtain a photoresist mask.

(5b) drying the sample and forming a second mask layer by photolithography and development techniques.

(5c) evaporating a second metallic layer on a surface of the second mask layer, to obtain a gate metal.

(5d) removing the second mask layer and the second metallic layer by a lift-off process and performing a rapid annealing, to obtain the gate electrode. As a result, the preparation of the device may be completed.

In the illustrated embodiment, the second mask layer is with a mask pattern of gate region, and the second metallic layer is a gate electrode metallic layer.

Further, in order to activate the injected fluorine ions, the annealing process in the sub-step (5d) can be carried out after the fluorine-ion injections in step 4 instead, in which an annealing temperature is above 340° C. and an annealing time is more than 10 minutes.

Optionally, the epitaxial substrate obtained in the step 1 of the illustrated embodiment can further include a cap layer arranged above the barrier layer, and then the forming of the source electrode and the drain electrode and subsequent processes are performed.

The high linearity HEMT device as provided by the illustrated embodiment has a simple process and a good compatibility, which is convenient to device preparation and process adjustment, and moreover an additional effect as introduced is small and thus can achieve higher feasibility and repeatability. Meanwhile, due to experiments on adjusting device transfer curves by fluorine-ion injections in the past research of enhanced devices have gained a lot of data, relevant research results can be directly referred to, parameters of respective discrete devices are easy to obtain, and a process flow is easy to control.

### Seventh Embodiment

A preparation method of the disclosure will be described below in detail by taking a high linearity HEMT device with fluorine injection concentrations progressively increased along a direction from one end to the other end as an example.

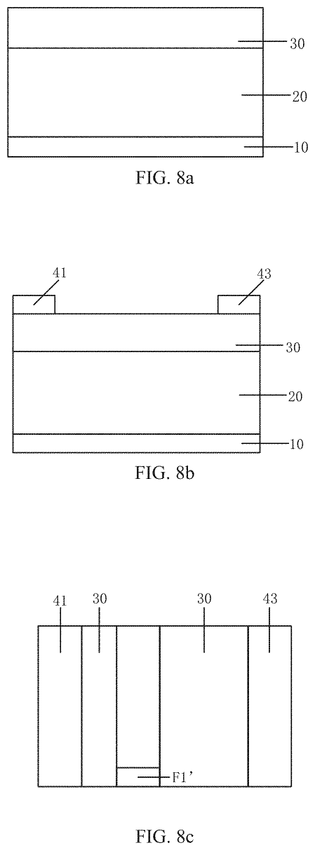

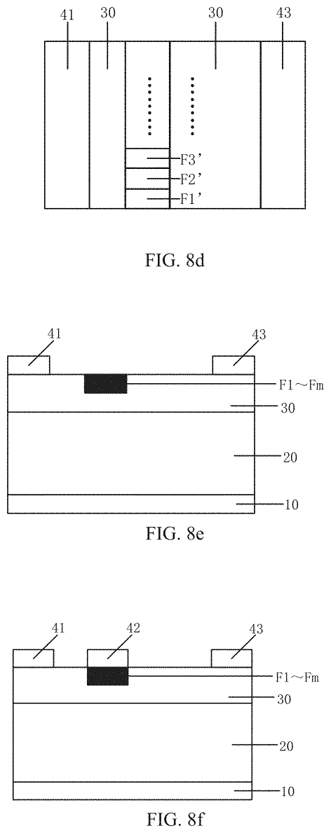

Referring to FIGS. 8a-8f, FIGS. 8a-8f are schematic views of a preparation process of the high linearity HEMT device shown in FIG. 1. The preparation process may specifically include the following steps S1-S5.

S1: obtaining a sample containing a sapphire substrate 10, a GaN buffer layer 20 and a AlGaN barrier layer 30, and cleaning the sample; as shown in FIG. 8a.

S2: forming a source electrode 41 and a drain electrode 43 on the AlGaN barrier layer 30, as shown in FIG. 8b.

Specifically, a photoresist glue is coated on a surface of the sample obtained by the step S1 and the coated photoresist glue is spun to obtain a photoresist mask, the photoresist mask then is dried, and afterwards photolithography and development techniques are used to form a mask pattern of source-drain regions.

Subsequently, a metallic layer is evaporated onto a surface of the sample formed with the mask pattern, to obtain source and drain metals.

Finally, the photoresist mask and the metallic layer are removed by a lift-off process and a rapid annealing process is carried out, and a source electrode 41 and a drain electrode 43 are obtained as a result.

S3: performing a mesa etching onto the sample to form an isolation mesa on the barrier layer 30.

Specifically, a photoresist glue is coated on a surface of the sample obtained by the step S2 and the coated photoresist glue is spun to obtain a photoresist mask, and then the photoresist mask is dried, and afterwards photolithography and development processes are carried out to form a mask pattern of mesa region.

Subsequently, the sample formed with the mask pattern is etched to thereby form the isolation mesa.

S4: injecting different concentrations of fluorine ions respectively into different regions of the AlGaN barrier layer 30 by multiple times to form m number of fluorine-doped regions with different fluorine-ion concentrations.

Specifically, a first fluorine-injection region F1′ is formed/defined, based on photolithographing, on the AlGaN barrier layer 30 corresponding to a gate region. In particular, a photoresist glue is first coated onto a surface of the sample obtained by the step S3 and the coated photoresist glue is spun to obtain a photoresist mask, and then the photoresist mask is dried, and afterwards photolithography and development are carried out to form a pattern of the first fluorine-injection region F1′ under the gate electrode, as shown in FIG. 8c.

After that, a fluorine-ion injection is performed onto the first fluorine-injection region F1′ by a fluorine-based reactive plasma etching process. A reaction gas is CF₄ plasma, a power is 60˜200 W, and an etching time is 50˜300 seconds. As a result, a fluorine-ion concentration in the first fluorine-injection region F1′ is n₁.

With reference to the above process associated with the formation of the first fluorine-injection region F1′ with the fluorine-ion concentration n₁, fluorine-injection regions F2′, F3′, . . . , Fm′ under the gate electrode can be formed based on photolithographing and then performed with fluorine-ion injections to respectively obtain fluorine-ion concentrations n₂, n₃, . . . , nₘ, and n₁<n₂< . . . <nₘ₋₁<nₘ, as shown in FIG. 8d. As a result, a series of fluorine-doped regions with fluorine-ion concentrations progressively increased from one end to the other end, e.g., from the first region F1 to the m-th region Fm are obtained, as shown in FIG. 8e.

Subsequently, the whole sample can be annealed to activate fluorine ions. Herein, an annealing temperature is above 340° C., and an annealing time is more than 10 minutes.

S5: forming a gate electrode 42 on a region of the barrier layer 30 between the source electrode 41 and the drain electrode 43 and corresponding to the fluorine-doped regions F1˜Fm, as shown in FIG. 8f.

Specifically, a photoresist glue is coated on a surface of the sample obtained by the step S4 and the coated photoresist glue is spun to form a photoresist mask, and then the photoresist mask is dried, and afterwards photolithography and development techniques are carried out to form a mask pattern of gate electrode region. Subsequently, a metallic layer is evaporated on the surface of the sample formed with the mask pattern. After that, the photoresist mask and the metallic layer are removed by a lift-off process to obtain the gate electrode 42. As a result, the preparation of the device can be completed/finished.

### Eighth Embodiment

On the basis of the above the sixth embodiment, a preparation method of a HEMT device with fluorine injection concentrations progressively increased along a direction from each of two opposite ends to a middle will be described below. The preparation method may specifically include the following steps A˜E.

Step A: obtaining a sample containing a sapphire substrate 10, a GaN buffer layer 20 and a AlGaN barrier layer 30, and cleaning the sample.

Step B: forming a source electrode 41 and a drain electrode 43 on AlGaN barrier layer 30.

Step C: performing a mesa etching onto the sample to form an isolation mesa on the barrier layer 30.

In the illustrated embodiment, steps A to C are the same as steps S1 to S3 of the third embodiment, and thus will not be repeated herein.

Step D: injecting different concentrations of fluorine ions into different regions of the AlGaN barrier layer 30 by multiple times, to form m number of fluorine-doped regions with different fluorine-ion concentrations.

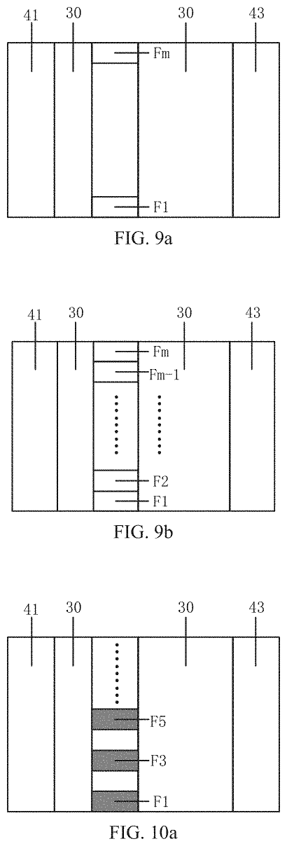

In the illustrated embodiment, fluorine-ion injection concentrations are progressively increased along a direction from each of the two opposite ends to the middle. Referring to FIG. 9a-9b, FIGS. 9a-9b are schematic views of fluorine injection processes provided by the illustrated embodiment of the disclosure.

Firstly, the first group of fluorine-injection regions F1 and Fm are formed, based on photolithographing, on the AlGaN barrier layer 30 corresponding to a gate region.

Specifically, a photoresist glue is coated on a surface of the sample obtained by the step C and the coated photoresist glue is spun to form a photoresist mask, and then the photoresist mask is dried, and afterwards photolithography and development are carried out to form a pattern of the first group of fluorine-injection regions under the gate electrode, as shown in FIG. 9a.

Subsequently, a fluorine-ion injection is performed onto the first group of fluorine-injection regions by a fluorine based reactive plasma etching process, so that fluorine-ion concentrations of the regions F1 and Fm both are n₁.

After that, with reference to the above process, a second group of fluorine-injection regions are formed under the gate electrode based on photolithographing and then injected with fluorine ions, and thereby fluorine-doped regions F2 and Fm−1 both with the fluorine-ion concentration n₂ are obtained, and so on, n₁<n₂<n₃< . . . , as shown in FIG. 9b. Herein, it should be understood that n₃ is a fluorine-ion concentration of both fluorine-doped regions F3 and Fm−2.

Finally, a series of fluorine-doped regions with fluorine-ion concentrations progressively increased along a direction from each of the two opposite ends to the middle (e.g., from each of the first fluorine-doped region F1 and the m-th fluorine-doped region Fm to a middle fluorine-doped region of the m number of fluorine-doped regions F1˜Fm) are formed in the barrier layer 30.

Step E: forming the gate electrode 42 on the barrier layer 30 between the source electrode 41 and the drain electrode 43 and corresponding to the fluorine-doped regions F1˜Fm. The step E specifically is the same as the step S5 of the fifth embodiment, and thus will not be repeated herein.

### Ninth Embodiment

On the basis of the above the sixth embodiment, a preparation of a HEMT device with two different fluorine-ion injection concentrations and fluorine-doped regions of the two different fluorine-ion injection concentrations being alternately arranged will be described below. The preparation method may specifically include the following steps.

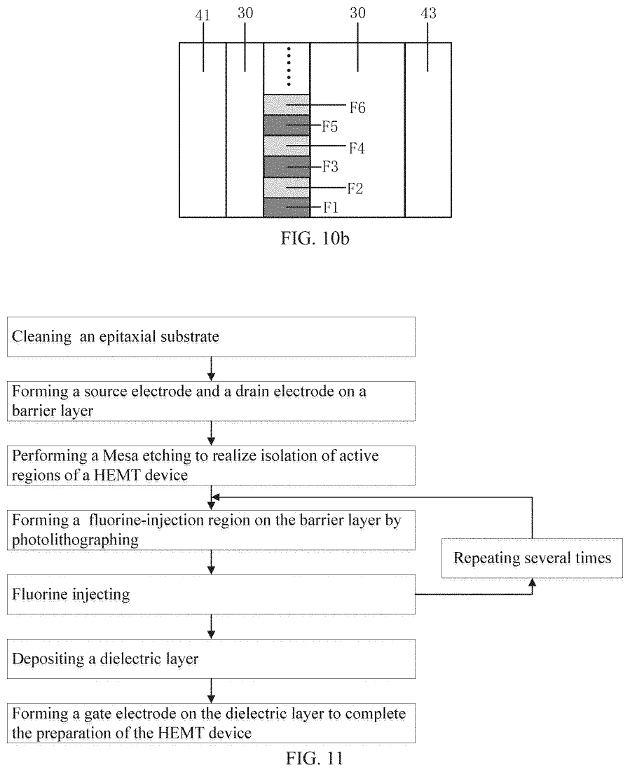

In particular, a sample with an isolation mesa of the barrier layer can be prepared as per the step 1 through step 3 in the sixth embodiment, and then fluorine-ion injections can be carried out. Referring to FIGS. 10a-10b, FIGS. 10a-10b are schematic views of another fluorine-ion injection process provided by an embodiment of the disclosure.

Firstly, kth fluorine-injection regions are formed on the barrier layer by photolithographing, and then a fluorine-ion injection is performed onto the k-th fluorine-injection regions to form multiple fluorine-doped regions with a same fluorine-ion concentration. k is odd numbers greater than 1, or k is even numbers greater than 1, and k≤m. The illustrated embodiment takes k being odd numbers for description, as shown in FIG. 10a. Afterwards, the rest regions (i.e., even numbered regions) are not injected with fluorine ions.

After the above operation, fluorine-doped regions with a certain concentration of fluorine ion and the rest regions with zero concentration of fluorine ion are formed and alternately arranged.

Further, after the fluorine-ion injection performed onto the odd numbered regions, the rest even numbered regions can be further injected with another concentration of ion. In particular, l-th fluorine-injection regions are formed on the barrier layer by photolithographing and then performed with another fluorine-ion injection to form multiple fluorine-doped regions with another same fluorine-ion concentration. l is even numbers greater than 1 when k is odd numbers greater than 1 (or, l is odd numbers greater than 1 when k is even numbers greater than 1), and l≤m.

So far, the fluorine-doped regions with two ion concentrations are formed and alternately arranged, as shown in FIG. 10b.

Finally, a gate electrode 42 is formed on the barrier layer 30 between the source electrode 41 and the drain electrode 43 and overlying the fluorine-doped regions F1˜Fm. Such step is specifically the same as the step S5 of the seventh embodiment, and thus will not be repeated herein.

### Tenth Embodiment

The illustrated embodiment provides a preparation method of a high linearity HEMT device, used to prepare the high linearity HEMT device as provided in the second embodiment. Referring to FIG. 11, FIG. 11 is a flowchart of a preparation method of the high linearity HEMT device shown in FIG. 4.

Compared with the HEMT device shown in FIG. 1, the HEMT device shown in FIG. 4 further includes a dielectric layer between the source electrode 41 and the drain electrode 43 and below the gate electrode 42. Correspondingly, in the preparation process, on the basis of the above method provided in the fourth embodiment, the dielectric layer can be deposited on the barrier layer after the step 4.

Specifically, a uniform Si₃N₄ or Al₂O₃ dielectric layer can be deposited on the barrier layer after the fluorine-ion injections are performed onto the barrier layer. A material, a thickness and a manufacturing process of the dielectric layer should be designed in consideration of their influences on gate control capability and suppression of gate leakage current for the device.

After the dielectric layer is prepared, the gate electrode is prepared on the dielectric layer to complete the preparation of the device.

Further, the other steps of the preparation method provided by the illustrated embodiment can refer to the above sixth embodiment, seventh embodiment and eighth embodiment, and thus will not be repeated herein.

### Eleventh Embodiment

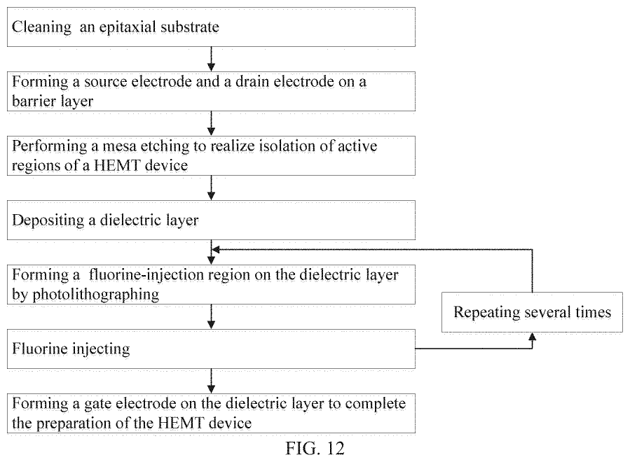

The illustrated embodiment provides a preparation method of a HEMT device, used to prepare the high linearity HEMT provided by the third embodiment. Referring to FIG. 12, FIG. 12 is a flowchart of a preparation method of the high linearity HEMT device shown in FIG. 5. The preparation method may specifically include the following steps A-F.

Step A: obtaining an epitaxial substrate and cleaning the epitaxial substrate. Herein, the epitaxial substrate includes a barrier layer.

Step B: forming a source electrode and a drain electrode on the barrier layer.

Step C: performing a mesa etching onto the epitaxial substrate to form an isolation mesa on the barrier layer.

Step D: depositing a dielectric layer on the barrier layer between the source electrode and the drain electrode.

Step E: injecting fluorine ions into the dielectric layer to form multiple fluorine-doped regions. The multiple fluorine-doped regions are located between the source electrode and the drain electrode.

Step F: forming a gate electrode overlying a region of the dielectric layer formed with the multiple fluorine-doped regions, to complete the preparation of the HEMT device.

Compared with the HEMT device shown in FIG. 4, the fluorine-doped regions of the HEMT device shown in FIG. 5 are located in the dielectric layer above the barrier layer. Therefore, in the specific preparation process, the dielectric layer is deposited first, and then the fluorine ion injections are carried out to form the fluorine-doped regions in the dielectric layer, and finally the gate electrode is formed on the dielectric layer.

Specifically, the method of forming multiple fluorine-doped regions by injections of fluorine ions into the dielectric layer associated with this embodiment is the same as the method of forming multiple fluorine-doped regions by injections of fluorine ions into the barrier layer as provided any one of the above seventh through ninth embodiments, and thus will not be repeated herein.

In an actual application, a process flow of a preparation method of a high linearity HEMT device provided by the disclosure may be different from the above process flow, for example, orders of forming the isolation mesa and forming the source electrode and the drain electrode can be interchanged. In addition, the structure of the device may further include an optimized structure(s) such as the nucleation layer, the interlayer, the cap layer and/or the passivation layer. Regardless of specific implementations, all structural, method, or functional transformations based on the device structure proposed by the disclosure should be included in the protection scope of the disclosure.

The above content is a detailed description of the disclosure in combination with specific preferred embodiments, and it cannot be considered that specific implementations of the disclosure are limited to these descriptions. For those ordinary skilled in the art of the disclosure, simple deductions or substitutions can be made without departing from the concept of the disclosure, which should all be regarded as belonging to the protection scope of the disclosure.

What is claimed is:

1. A high electron mobility transistor (HEMT) device, comprising:
a substrate layer (10), a buffer layer (20), a barrier layer (30) and a metallic electrode layer (40) sequentially arranged in that order from bottom to top;
wherein the metallic electrode layer (40) comprises a source electrode (41), a gate electrode (42) and a drain electrode (43) sequentially arranged in that order from left to right;
wherein the barrier layer (30) comprises m number of negatively-charged-ion doped regions F1˜Fm arranged in sequence, where m is a positive integer and m≥2, and negatively-charged-ion concentrations of the m number of negatively-charged-ion doped regions comprise at least two different negatively-charged-ion concentrations.

2. The HEMT device according to claim 1, wherein the m number of negatively-charged-ion doped regions F1˜Fm are m number of fluorine-doped regions arranged in sequence.

3. The HEMT device according to claim 2, further comprising: a dielectric layer (50), disposed between the source electrode (41) and the drain electrode (43); wherein the gate electrode (42) is disposed above the dielectric layer (50).

4. The HEMT device according to claim 2, wherein the m number of negatively-charged-ion doped regions F1˜Fm are located below the gate electrode (42) and arranged in sequence along a widthwise direction of the gate electrode (42).

5. The HEMT device according to claim 4, wherein the negatively-charged-ion concentrations of the m number of negatively-charged-ion doped regions F1˜Fm are progressively increased or decreased along a direction from the negatively-charged-ion doped region F1 to the negatively-charged-ion doped region Fm.

6. The HEMT device according to claim 4, wherein the negatively-charged-ion concentrations of the m number of negatively-charged-ion doped regions F1˜Fm are progressively increased or decreased along a direction from each of the negatively-charged-ion doped region F1 and the negatively-charged-ion doped region Fm to a middle negatively-charged-ion doped region of the m number of negatively-charged-ion doped regions F1˜Fm.

7. The HEMT device according to claim 4, wherein the negatively-charged-ion concentrations of the m number of negatively-charged-ion doped regions F1˜Fm comprise two different negatively-charged-ion concentrations, the negatively-charged-ion doped regions of the m number of negatively-charged-ion doped regions F1˜Fm having one of the two different negatively-charged-ion concentrations and the negatively-charged-ion doped regions of the m number of negatively-charged-ion doped regions F1˜Fm having the other one of the two different negatively-charged-ion concentrations are alternately arranged.

8. The HEMT device according to claim 4, further comprising at least one selected from a group consisting of a nucleation layer, an interlayer, a cap layer and a passivation layer; wherein,
the nucleation layer is arranged between the substrate layer (10) and the buffer layer (20);
the interlayer is arranged between the buffer layer (20) and the barrier layer (30);
the cap layer is arranged between the barrier layer (30) and the metallic electrode layer (40);
the passivation layer is arranged above the barrier layer (30) and located among the source electrode (41), the gate electrode (42) and the drain electrode (43).

9. A HEMT device, comprising:
a substrate layer (10), a buffer layer (20), a barrier layer (30) and a metallic electrode layer (40) sequentially arranged in that order from bottom to top;
wherein the metallic electrode layer (40) comprises a source electrode (41), and a drain electrode (43) respectively located at two ends of itself, a dielectric layer (50) is disposed between the source electrode (41) and the drain electrode (43), and a gate electrode (42) of the metallic electrode layer (40) is disposed on the dielectric layer (50);
wherein the dielectric layer (50) comprises m number of negatively-charged-ion doped regions F1˜Fm arranged in sequence, where m is a positive integer and m≥2, and negatively-charged-ion concentrations of the m number of negatively-charged-ion doped regions comprise at least two different negatively-charged-ion concentrations.

10. The HEMT device according to claim 9, wherein the m number of negatively-charged-ion doped regions F1˜Fm are m number of fluorine-doped regions arranged in sequence.

11. The HEMT device according to claim 10, wherein the m number of negatively-charged-ion doped regions F1˜Fm are located below the gate electrode (42) and arranged in sequence along a widthwise direction of the gate electrode (42).

12. The HEMT device according to claim 11, wherein the negatively-charged-ion concentrations of the m number of negatively-charged-ion doped regions F1˜Fm are progressively increased or decreased along a direction from the negatively-charged-ion doped region F1 to the negatively-charged-ion doped region Fm.

13. The HEMT device according to claim 11, wherein the negatively-charged-ion concentrations of the m number of negatively-charged-ion doped regions F1˜Fm are progressively increased or decreased along a direction from each of the negatively-charged-ion doped region F1 and the negatively-charged-ion doped region Fm to a middle negatively-charged-ion doped region of the m number of negatively-charged-ion doped regions F1˜Fm.

14. The HEMT device according to claim 11, wherein the negatively-charged-ion concentrations of the m number of negatively-charged-ion doped regions F1˜Fm comprise two different negatively-charged-ion concentrations, the negatively-charged-ion doped regions of the m number of negatively-charged-ion doped regions F1˜Fm having one of the two different negatively-charged-ion concentrations and the negatively-charged-ion doped regions of the m number of negatively-charged-ion doped regions F1˜Fm having the other one of the two different negatively-charged-ion concentrations are alternately arranged.

15. The HEMT device according to claim 11, further comprising at least one selected from a group consisting of a nucleation layer, an interlayer, a cap layer and a passivation layer; wherein,
the nucleation layer is arranged between the substrate layer (10) and the buffer layer (20);
the interlayer is arranged between the buffer layer (20) and the barrier layer (30);
the cap layer is arranged between the barrier layer (30) and the metallic electrode layer (40);
the passivation layer is arranged above the barrier layer (30) and located among the source electrode (41), the gate electrode (42) and the drain electrode (43).
